(19) United States
(12) Patent Application Publication
(10) Pub. No.: US 2025/0098110 A1
(43) Pub. Date: Mar. 20, 2025

(54) CONDUCTOR MEMBER WITH COOLING STRUCTURE

(71) Applicant: Yazaki Corporation, Tokyo (JP)

(72) Inventors: Junya HIGASHI, Kakegawa-shi (JP); Hiroyuki Tanaka, Kakegawa-shi (JP); Kazuki Shirosaka, Kakegawa-shi (JP)

(73) Assignee: Yazaki Corporation, Tokyo (JP)

(21) Appl. No.: 18/805,612

(22) Filed: Aug. 15, 2024

(30) Foreign Application Priority Data
Sep. 20, 2023 (JP) 2023-152098

(51) Int. Cl. H05K 7/20; H01B 5/02

(52) U.S. Cl. CPC H05K 7/20272; H01B 5/02; H05K 7/20472

(57) ABSTRACT

A conductor member with cooling structure includes a conductor member formed of a conductive metal in a strip shape, wherein one end side is connected to a component terminal of an electrical/electronic member, and the other end side is connected to an electrical connection target; a refrigerant case formed of an insulative resin to accommodate refrigerant, wherein a pair of refrigerant inlet/outlet ports are provided in the refrigerant case; and a heat transmission member with a first portion and a second portion that enters the refrigerant case to be connected to the refrigerant case in a state of being in contact with the refrigerant so as to connect the conductor member and the refrigerant case with each other, while receive heat generated in the conductor member by the first portion and transmit the heat from the second portion to the refrigerant flowing in the refrigerant case.

### TECHNICAL FIELD

The present invention relates to a conductor member with cooling structure that connects component terminals of electrical and electronic components as an electrical connection target while performing cooling to itself.

### BACKGROUND ART

Conventionally, a cooling structure configured to transfer heat of a conductor member connected to component terminals, as an electrical connection target, of an electrical and electronic component to a bottom wall of a device housing to dissipate the heat is known (for example, see Patent Document 1). The cooling structure according to Patent Document 1 is configured as a structure to transfer the heat of the conductor member that is made of metal to the bottom wall via an insulation member so as to prevent electrical leakage and perform the heat dissipation of the conductor member.

### CITATION LIST

Patent Documents

[Patent Document 1] JP 2020-127302A

### SUMMARY OF THE INVENTION

### Technical Problem

Here, according to the conductor member with cooling structure adopting the cooling structure of the above-described Patent Document 1, there are many inclusion materials between the conductor member and the bottom wall as a cooling plate such that the cooling efficiency tends to be low.

Accordingly, the present invention is focused on the above-described technical problem and an object of the present invention is to provide a conductor member with cooling structure which can improve the cooling efficiency with respect to the conductor member.

### Solution to Problem

In order to solve the above-identified problem, a conductor member with cooling structure is characterized by including a conductor member formed of a conductive metal in a strip shape, wherein one end side is connected to a component terminal of a predetermined electrical/electronic member, and the other end side is connected to an electrical connection target of the electrical/electronic member to be energized; a refrigerant case formed of an insulative resin to accommodate refrigerant, wherein a pair of refrigerant inlet/outlet ports for the refrigerant to enter in and exit out thereof are provided in the refrigerant case; and a heat transmission member with a first portion connected to the conductor member and a second portion that enters the inside of the refrigerant case to be connected to the refrigerant case in a state of being in contact with the refrigerant so as to connect the conductor member and the refrigerant case with each other, while receive heat generated in the conductor member by the first portion and transmit the heat from the second portion to the refrigerant flowing in the refrigerant case.

### Effect of the Invention

According to the above-described conductor member with cooling structure, it is possible to improve the cooling efficiency with respect to the conductor member.

### BRIEF DESCRIPTION OF THE DRAWINGS

FIG. 1 is a perspective view showing a conductor member with cooling structure according to an embodiment.

FIG. 2 is an exploded perspective view showing the conductor member with cooling structure shown in FIG. 1.

FIG. 3 is a cross-sectional view showing the conductor member with cooling structure taken along line V11-V11 in FIG. 1.

FIG. 4 is a cross-sectional view showing the conductor member with cooling structure taken along line V12-V12 in FIG. 1.

### DESCRIPTION OF EMBODIMENTS

Hereinafter, an embodiment of a conductor member with cooling structure will be described.

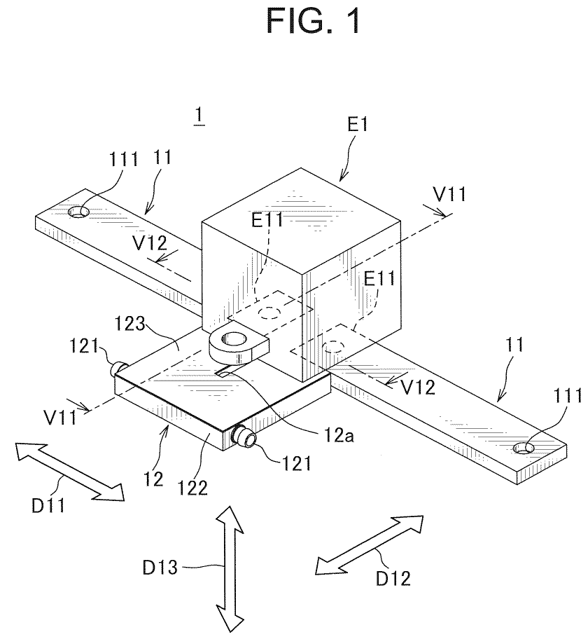

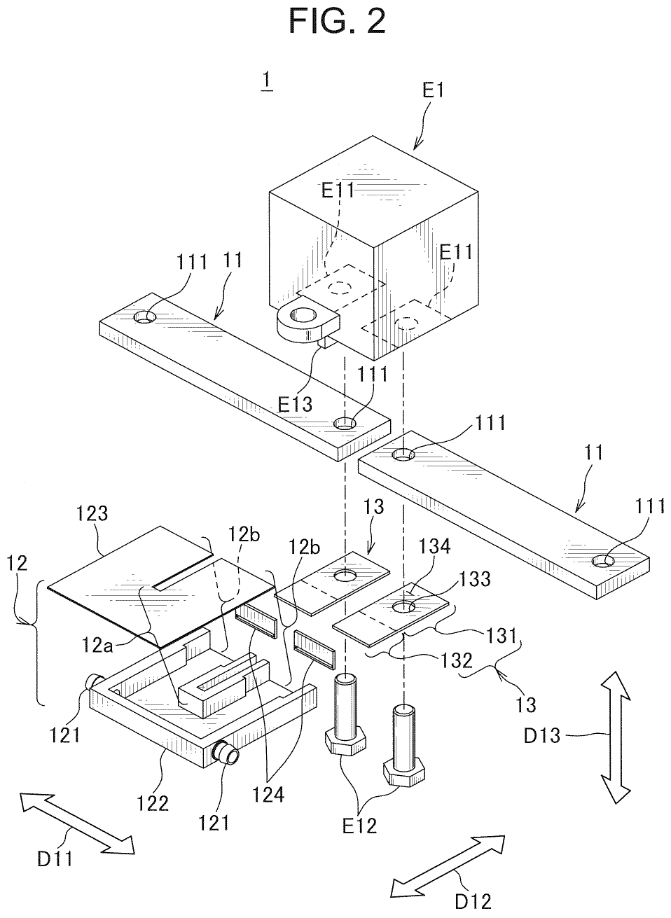

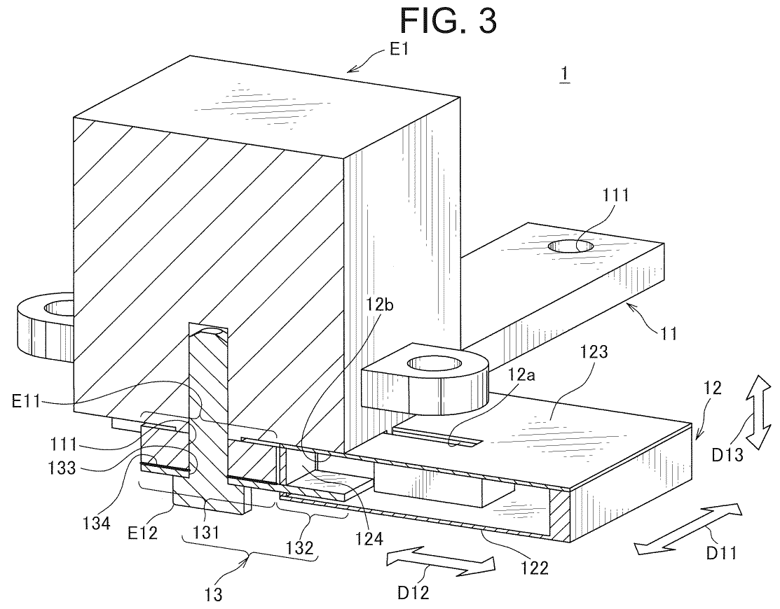

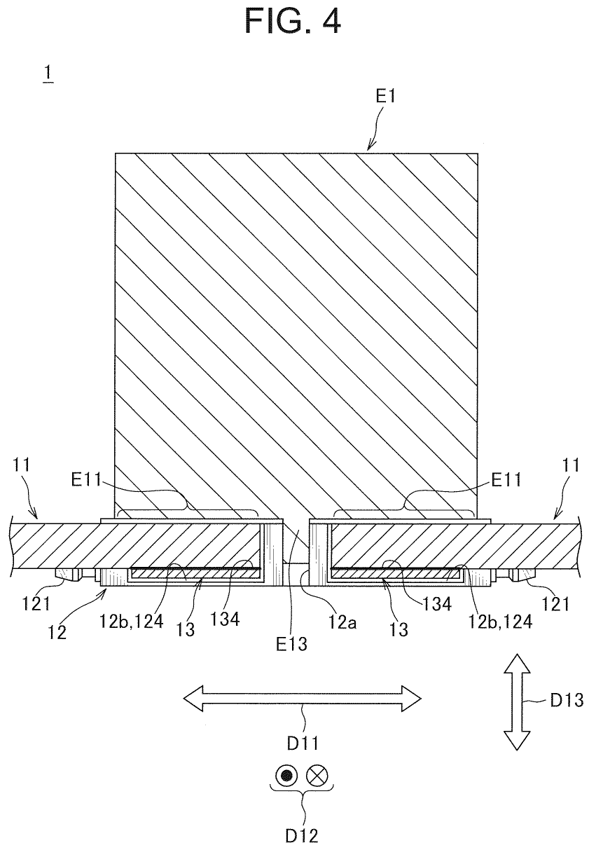

FIG. 1 is a perspective view showing a conductor member with cooling structure according to an embodiment. FIG. 2 is an exploded perspective view showing the conductor member with cooling structure shown in FIG. 1. FIG. 3 is a cross-sectional view showing the conductor member with cooling structure taken along line V11-V11 in FIG. 1. FIG. 4 is a cross-sectional view showing the conductor member with cooling structure taken along line V12-V12 in FIG. 1.

A conductor member with cooling structure 1 according to the present embodiment is a member for connecting each component terminal E11 in a relay as an electrical/electronic member E1 to an electrical connection target of this electrical/electronic member E1. A pair of component terminals E11 are provided in the electrical/electronic member E1 and the conductor member with cooling structure 1 includes a pair of conductor member 11, a single refrigerant case 12, and a pair of heat transmission members 13.

The conductor member 11 is formed of a conductive metal such as copper and the like in a rectangular strip shape as an energized busbar with one end side being connected to the component terminal E11 of the electrical/electronic member E1 and the other end side being connected to an electrical connection target of the electrical/electronic member E1. According to the present embodiment, the conductor members 11 are provided in a pair such that the conductor members 11 are connected with a pair of component terminals E11 provided in the electrical/electronic member E1 by one-to-one correspondence and each of the conductor member 11 extends in an arrangement direction D11 of the component terminal E11. Both ends of each conductor member 11 are provided with penetration holes 111 through which screws for fastening E12 pass so as to be connected with the component terminals E11 and the electrical connection target by the screw fastening.

The refrigerant case 12 is a case that is made of an insulation resin and has a flat rectangular box-shaped appearance for accommodating a refrigerant, and is a member provided with a pair of refrigerant inlet/outlet ports 121 for allowing the refrigerant to enter and exit the case. According to the present embodiment, as the cooling refrigerant, the water as a conductive fluid is adopted. The refrigerant case 12 is disposed such that one side in the flat rectangular box-shaped appearance faces a connection portion between the pair of conductor members 11 and the pair of component terminals E11 in the electrical/electronic member E1. Also, the pair of refrigerant inlet/outlet ports 121 are provided near the other side being opposite to the one side at the connection portion side such that the refrigerant flows along the arrangement direction D11. The pair of refrigerant inlet/outlet ports 121 are formed in one-on-one relationship near the other side of the pair of opposing side walls intersecting the arrangement direction D11 of the component terminals E11 in the refrigerant case 12 arranged as described above, wherein one side is formed as the inlet port of the refrigerant and the other one side is formed as the outlet port thereof.

Here, according to the present embodiment, the electrical/electronic member E1 has the rectangular block-shaped appearance, wherein a pair of component terminals E11 are provided on one surface among the six surfaces. Also, on the one surface, a rib-between-terminals E13 stands to extend between the pair of component terminals E11 while intersecting the arrangement direction D11 of the component terminal E11. In the refrigerant case 12, from the one side at the side of the connection portion between the pair of conductor members 11 and the pair of component terminals E11, a slit portion 12a for receiving this rib-between-terminals E13 is formed therein. The slit portion 12a is formed by cutting off the refrigerant case 12 to a position slightly beyond a center of the refrigerant case 12 in an intersecting direction D12 with respect to the arrangement direction D11. The refrigerant case 12 is disposed such that the rib-between-terminals E13 of the electrical/electronic member E1 is fitted into this slit portion 12a. The refrigerant case 12 has a C-shape in a planar view from a thickness direction D13 thereof, wherein a gap between a pair of arms in the C-shape becomes the slit portion 12a and the front-end side of each of the pair of arms becomes a component inlet port 12b for a heat-transmission member 13 described below to enter. Also, the pair of refrigerant inlet/outlet ports 121 are provided at the root side of the pair of arms respectively such that the refrigerant flowing into the refrigerant inlet/outlet port 121 at one side absorbs the heat from the heat transmission member 13 entering from the component inlet port 12b, and the refrigerant flows out from the refrigerant inlet/outlet ports 121 at the other side to dissipate the heat. According to the present embodiment, such refrigerant case 12 formed in the thin and flat rectangular block shape and in such a C-shape includes a case main body 122 and a case lid 123 wherein each is formed in the C-shape, and the pair of refrigerant inlet/outlet ports 121 are attached to the side wall of the case main body 122. The case body 122 and the case lid 123 are bonded together by an adhesion using an adhesive, a welding by heating and melting the bonded portion, or the like.

The heat transmission member 13 is a member connected to this refrigerant case 12 in a state in which a first portion 131 is connected with the conductor member 11 and a second portion 132 enters the inside of the refrigerant case 12 to come into contact with the refrigerant. According to the present embodiment, the heat transmission member 13 is a member formed of the conductive metal such as the copper or the like in the rectangular strip shape, wherein one end side thereof becomes the first portion 131 and the other end side thereof becomes the second portion 132. Here, the connection between the first portion 131 of the heat transmission 13 and the conductor member 11 is a joint-fastening connection together with the one end side of the conductor member 11 with respect to the component terminal E11 by the screw fastening. For the joint-fastening connection, the screw penetration hole 133 through which the screw E12 passes is provided in the first portion 131 of the heat transmission member 13. Also, the pair of such heat transmission members 13 are provided such each heat transmission member 13 is connected to the first portion 131 of each of the pair of conductor members 11 by one-to-one correspondence. Each heat transmission member 13 connects the conductor member 11 and the refrigerant case 12 with each other by connecting the first portion 131 with the conductor member 11 and connecting the second portion 132 with the refrigerant case 12. Furthermore, the second portion 132 entering the inside of the refrigerant case 12 comes into contact with the refrigerant such that the heat generated in the conductor member 11 when energized is received by the first portion 131 and transmitted to the refrigerant flowing from the second portion 132 to the inside of the refrigerant case 12.

In the refrigerant case 12, as described above, the pair of component inlet ports 12b are formed at the side of the connection portion between the conductor member 11 and the component terminal E11. Also, the second portions 132 of the pair of heat transmission members 13 connected with the component terminal E11 together with the conductor member 11 enter the pair of component inlet ports 12b by one-to-one correspondence. Furthermore, regarding the refrigerant case 12, each component inlet port 12b in which the second portion 132 enters is sealed by a sealing member 124 made of the rubber.

Here, each heat transmission member 13 is fastened and connected with the conductor member 11 in a state in which the first portion 131 is superimposed on a surface at one side between the front surface and the back surface of the conductor member 11, more specifically the surface on the opposite side of the component terminal E11. Also, each heat transmission member 13 extends from a side edge in the conductor member 11 in an intersection direction with respect to the side edge, that is, in the intersection direction D12 with respect to the arrangement direction D11 of the component terminal E11. Furthermore, a pair of heat transmission members 13 extend in the above-described intersection direction D12 from each side edge at the same side between the pair of conductor members 11. Also, in the refrigerant case 12, a pair of component inlet ports 12b arranged side by side in the arrangement direction D11 to sandwich the above-described slit portion 12a are provided such that the second portion 132 of each of the pair of heat transmission members 13 enters therein in a state of being arranged in the above-described arrangement direction D11 side by side. Also, with regard to the intersection direction D12, a pair of refrigerant inlet/outlet ports 121 are provided by one-to-one correspondence near the opposite portion of the component inlet ports 12b on the pair of opposing side walls of the refrigerant case 12. The refrigerant flows along the arrangement direction D11 near this opposite portion inside the refrigerant case 12 so as to absorb the heat from the second portion 132 of the pair of heat transmission members 13 during the flow.

According to the present embodiment, the insulation processing is applied to following locations such that the conductor member 11 and the refrigerant each having the conductivity are electrically isolated from each other. That is, at least one location of the connection location between the conductor member 11 and the heat transmission member 13 each being formed of conductive metal, or the contact location with the refrigerant in the heat transmission member 13 is applied with the insulation processing. According to the present embodiment, insulation paint 134 is painted on the contact surface in the heat transmission member 13 with the conductor member 11 as such insulation processing.

According to the conductor member with cooling structure 1 of the above-described embodiment, the heat generated in the conductor member 11 is transmitted to the refrigerant inside the refrigerant case 12 via the heat transmission member 13 only. Accordingly, according to the above-described conductor member with cooling structure 1, it is possible to improve the cooling efficiency with respect to the conductor member 11 when compared with a structure that transmits the heat to a cooling plate via multiple inclusions or the like.

Here, according to the present embodiment, the conductor member 11 is a configuration wherein one end side thereof is connected to the component terminal E11 by the screw fastening, and regarding the heat transmission member 13, the first portion 131 is fastened together with the one end side of the conductor member 11 and connected to the component terminal E11 by the screw fastening. In the conductor member 11, the heat is most likely to be generated when the electricity is applied to the electrical and electronic member E1 at the connection location with the component terminal E11. According to the above-described configuration, since the first portion 131 in the heat transmission member 13 is fastened together with the one end side of the conductor member 11 and connected to the component terminal E11, it is possible to transmit the heat generated when energized to the refrigerant more effectively so as to further improve the cooling efficiency.

Also, according to the present embodiment, regarding the refrigerant case 12, the component inlet port 12b in the state in which the second portion 132 of the heat transmission member 13 has entered therein is sealed by the sealing member 124. According to this configuration, since the second portion 132 of the heat transmission member 13 enters the component inlet port 12b in the refrigerant case 12 in the state in which the component inlet port 12b is sealed, it is possible to adopt a liquid cooling type cooling structure with high cooling efficiency by using the liquid such as the water or the like as the refrigerant.

Also, according to the present embodiment, the first portion 131 of the heat transmission member 13 in the rectangular strip shape is superimposed on the surface on one side in the conductor member 11 while the second portion 132 of the heat transmission member 13 extending in the intersection direction D12 from one side edge thereof is entering the inside of the refrigerant case 12. According to this configuration, an extension length of the heat transmission member 13 from the conductor member 11 can be suppressed to allow the contact with the refrigerant inside the refrigerant case 12 such that the cooling efficiency can be further improved.

Also, according to the present embodiment, the refrigerant is the water as the fluid having the conductivity, and the heat transmission member 13 is formed of the conductive metal. Then, the insulation processing is applied to at least one location of the connection location between the conductor member 11 and the heat transmission member 13 each being formed of conductive metal, or the contact location with the refrigerant in the heat transmission member 13 such that the conductor member 11 and the refrigerant each having the conductivity are electrically isolated from each other. More specifically, the insulation processing by the painting of the insulation paint 134 in the connection location in the heat transmission member 13 with the conductor member 11 as such insulation processing. According to this configuration, the heat transmission member 13 is formed of the conductive metal with high thermal conductivity so as to achieve further improvement in the cooling efficiency, and a situation such as that the conductor member 11 is short-circuited to an unintentional location via the refrigerant or the like can be effectively prevented. Also, assuming that such short-circuit is prevented, the common refrigerant having the conductivity, such as the water, can be adopted.

Also, according to the present embodiment, a pair of heat transmission members 13 are provided by one-to-one correspondence with each first portion 131 of the pair of conductor members 11, and each second portion 132 of the pair of heat transmission members 13 enters the inside of the refrigerant case 12 to come into contact with the refrigerant. According to this configuration, regarding the pair of conductor members 11 connected to the pair of component terminals E11, such as +/− terminals, which are often found in the electrical and electronic component E1, it is possible to efficiently cool the heat when energized by the refrigerant of the single refrigerant case 12.

Also, according to the present embodiment, each second portion 132 of the pair of heat transmission members 13 enters the refrigerant case 12 in the state of being arranged side by side in the arrangement direction D11, and the pair of refrigerant inlet/outlet ports 121 are provided and arranged such that the refrigerant flows along the arrangement direction D11. According to this configuration, the flow path of the refrigerant is configured along the pair of conductor members 11 wherein each extending along the arrangement direction D11 of the component terminal E11 so as to optimize the arrangement of the conductor member 11 and the refrigerant case 12 to achieve the miniaturization of the conductor member with cooling structure 1.

The above-described embodiment is merely used to show a typical embodiment of the conductor member with cooling structure. The conductor member with cooling structure is not limited thereto and can be implemented as various modifications.

For example, according to the above-described embodiment, as an example of the conductor member with cooling structure, the conductor member with cooling structure 1 for connecting each of the pair of component terminals E11 as the electrical connection target in the relay as the electrical/electronic member E1 is shown. However, the conductor member with cooling structure is not limited thereto, and the electrical/electronic member to be connected may be electrical members other than the relay or other electronic members.

Also, according to the above-described embodiment, as an example of the conductor member with cooling structure, the conductor member with cooling structure 1 being a liquid cooling type in which the water being the conductive liquid flows as the refrigerant is shown. However, the conductor member with cooling structure is not limited thereto, and the refrigerant may be a non-conductive liquid or a gas for air cooling. In a case in which the non-conductive liquid or the gas for air cooling is adopted, the insulation processing in the conductor member and the heat transmission member is unnecessary.

Also, according to the above-described embodiment, as an example of the conductor member with cooling structure, the conductor member with cooling structure in which the pair of refrigerant inlet/outlet ports 121 are provided on the pair of side walls in the refrigerant case 12 by one-to-one correspondence is shown. However, the conductor member with cooling structure is not limited thereto, and the pair of refrigerant inlet/outlet ports may be attached to any position in the refrigerant case.

Also, according to the above-described embodiment, as an example of the refrigerant case, the refrigerant case 12 including the case main body 122 and the case lid 123, wherein both are joined together by adhering or welding is shown. However, the refrigerant case is not limited thereto, and as long as the case is made of the insulation resin for accommodating the refrigerant, the specific elemental configuration may adopt any possible configuration.

Also, according to the above-described embodiment, as an example of the heat transmission member, the heat transmission member 13 which is fastened together with the conductor member 11 and connected with the component terminal E11 by the screw fastening is shown. However, the heat transmission member is not limited thereto, and the heat transmission member may be connected to a portion separating apart from the connection location in the conductor member to connect the component terminal. However, as described above, according to the joint fastening and connection between the heat transmission member 13 and the conductor member 11, it is possible to further improve the cooling efficiency.

Also, according to the above-described embodiment, as an example of the refrigerant case, the refrigerant case 12 in which the component inlet port 12b in the state where the second portion 132 of the heat transmission member 13 has entered therein is sealed by the rubber sealing member 124 is shown. However, the refrigerant case is not limited thereto, and it is possible to not to specifically perform the sealing of the component inlet port, while it is possible to use the gas as the refrigerant to make it to flow outside from the component inlet port. However, by sealing the component inlet port 12b of the refrigerant case 12, as described above, it is possible to adopt the cooling structure of the liquid cooling type with the high cooling efficiency. Also, regarding this sealing member, it is not limited to be made of the rubber, the sealing member only has to be able to seal the component inlet port, and the specific material is not particularly limited.

Also, according to the above-described embodiment, as an example of the heat transmission member, the heat transmission member 13 in which the first portion 131 is superimposed on the conductor member 11 and extend from one side edge thereof in the intersection direction D12, and the second portion 132 enters the inside of the refrigerant case 12 is shown. However, the heat transmission member is not limited thereto, and the relative arrangement of the conductor member and the refrigerant case may adopt any possible arrangement. However, according to the configuration in which the heat transmission member 13 being arranged to intersect the conductor member 11 is configured to enter the refrigerant case 12, as described above, it is possible to suppress the extension length of the heat transmission member 13 from the conductor member 11 to further improve the cooling efficiency.

Also, according to the above-described embodiment, as an example of the conductor member with cooling structure, the conductor member with cooling structure 1 in which the heat transmission member 13 made of the conductive metal is used and the insulation processing is applied such that the conductor member 11 and the water as the refrigerant are electrically isolated from each other is shown. However, the conductor member with cooling structure is not limited thereto, and insulative elements may be adopted as the heat transmission member and the refrigerant wherein the insulation processing is unnecessary. However, as described above, it is possible to achieve the further improvement of the cooling efficiency by using the heat transmission member made of the conductive metal with high thermal conductivity and use the water as the common refrigerant having the conductivity by performing the suitable insulation processing. Furthermore, the locations where the insulation processing is applied are not limited to the contact locations with the conductor member 11 in the heat transmission member 13 as shown in the above-described embodiment. The locations where the insulation processing is applied may be at least either of the connection location between the conductor member and the heat transmission member or the contact location with the refrigerant in the heat transmission member.

Also, according to the above-described embodiment, as an example of the conductor member with cooling structure, the conductor member with cooling structure 1 in which the heat transmission members 13 are provided in a pair wherein each first portion 131 is connected to each of the pair of conductor members 11 by one-to-one correspondence is shown. However, the conductor member with cooling structure is not limited thereto, only one heat transmission member may be provided to connect to the one conductor member. Or in another case, the conductor member with cooling structure may be configured that multiple heat transmission members are provided to connect to a plurality of conductor members being equal to or more than three by one-to-one correspondence. However, according to the configuration in which the pair of heat transmission members 13 are provided in the pair of conductor members 11, as described above, it is possible to efficiently cool the pair of conductor members 11 connected to the pair of component terminals E11 which are often found in the electrical and electronic component E1.

Also, according to the above-described embodiment, as an example of the conductor member with cooling structure, the conductor member 1 with cooling structure in which inside the refrigerant case 12, the second portions 132 of the pair of heat transmission members 13 are arranged in the arrangement direction D11, and the refrigerant flows along this arrangement direction D11 is shown. However, the conductor member with cooling structure is not limited thereto, and regarding the arrangement of the second portions of the heat transmission member inside the refrigerant case and the flowing direction of the refrigerant, they may be appropriately set. However, as described above, by setting the arrangement of the second portions 132 of the heat transmission member 13 and the flowing direction of the refrigerant along the arrangement direction D11 of the component terminal E11 in which the pair of conductor members 11 extend, it is possible to achieve the miniaturization of the conductor member with cooling structure 1.

### REFERENCE SIGNS LIST

1, conductor member with cooling structure
11 conductor member
12 refrigerant case
12a slit portion
12b component inlet port
13 heat transmission member
111, 133 screw penetration hole
121 refrigerant inlet/outlet port
122 case main body
123 case lid
124 sealing member
131 first portion
132 second portion
134 insulation paint
D11 arrangement direction
D12 intersecting direction
D13 thickness direction
E1 electrical/electronic member
E11 component terminal
E12 screw
E13 rib-between-terminal

What is claimed is:

1. A conductor member with cooling structure, comprising:
a conductor member formed of a conductive metal in a strip shape, wherein one end side is connected to a component terminal of a predetermined electrical/electronic member, and the other end side is connected to an electrical connection target of the electrical/electronic member to be energized;
a refrigerant case formed of an insulative resin to accommodate refrigerant, wherein a pair of refrigerant inlet/outlet ports for the refrigerant to enter in and exit out thereof are provided in the refrigerant case; and
a heat transmission member with a first portion connected to the conductor member and a second portion that enters the inside of the refrigerant case to be connected to the refrigerant case in a state of being in contact with the refrigerant so as to connect the conductor member and the refrigerant case with each other, while receive heat generated in the conductor member by the first portion and transmit the heat from the second portion to the refrigerant flowing in the refrigerant case.

2. The conductor member with cooling structure according to claim 1,
wherein in the conductor member, the one end side is connected to the component terminal by a screw fastening, and
in the heat transmission member, the first portion is fastened together with the one end side of the conductor member to be connected to the component terminal by the screw fastening.

3. The conductor member with cooling structure according to claim 1, wherein in the refrigerant case, a component inlet port into which the second portion of the heat transmission member enters is formed, and the component inlet port is sealed by a predetermined sealing member in a state in which the second portion has entered the component inlet port.

4. The conductor member with cooling structure according to claim 1, wherein the heat transmission member is formed in a strip shape, the first portion is superimposed on one of a front surface and a back surface of the conductor member, and the heat transmission member extends from a side edge in the conductor member in an intersecting direction with respect to the side edge such that the second portion enters the inside of the refrigerant case.

5. The conductor member with cooling structure according to claim 1,
wherein the refrigerant is a fluid having conductivity,
the heat transmission member is formed of a conductive metal, and
at least one location between a connection location of the conductor member and the heat transmission member and a contact location with the refrigerant in the heat transmission member is applied with an insulation processing such that the conductor member and the refrigerant are electrically isolated from each other.

6. The conductor member with cooling structure according to claim 1,
wherein the component terminals are provided in a pair in the electrical/electronic member,
the conductor members are provided in a pair such that the pair of conductor members are connected to the pair of component terminals by one-to-one correspondence and each thereof extends in an arrangement direction of the component terminals, and
the heat transmission members are provided in a pair such that the first portion of each of the pair of heat transmission members is connected to each of the pair of conductor members, and
the second portion of each of the pair of heat transmission members enters the inside of the refrigerant case to come into contact with the refrigerant.

7. The conductor member with cooling structure according to claim 6.
wherein the pair of heat transmission members extend from the side edge at the same side between the pair of conductor members to intersect the arrangement direction, and
the second portion of each of the pair of heat transmission members enters the refrigerant case in a state of lining up in the arrangement direction, and the pair of refrigerant inlet/outlet ports are arranged such that the refrigerant flows along the arrangement direction.
